(19) United States
(12) Patent Application Publication
(10) Pub. No.: US 2025/0172880 A1
(43) Pub. Date: May 29, 2025

(54) OPTICAL PROXIMITY CORRECTION (OPC) METHOD, AND METHOD OF MANUFACTURING MASK BY USING THE SAME

(71) Applicant: Samsung Electronics Co., Ltd., Suwon-si (KR)

(72) Inventors: Jihyeon Woo, Suwon-si (KR); Sujin Oh, Suwon-si (KR); Heungsuk Oh, Suwon-si (KR); Jeeeun Jung, Suwon-si (KR)

(21) Appl. No.: 18/795,463

(22) Filed: Aug. 6, 2024

(30) Foreign Application Priority Data
Nov. 27, 2023 (KR) 10-2023-0167151

(51) Int. Cl. G03F 7/00

(52) U.S. Cl. CPC G03F 7/70441

(57) ABSTRACT

An optical proximity correction (OPC) method includes generating a retarget curve line of a polygonal pattern layout of a target pattern, generating first control points on the retarget curve line, generating a first curvilinear pattern layout based on the first control points, extracting a contour of the target pattern through a OPC simulation, calculating an edge placement error, determining whether to re-perform the extracting, when it is determined to re-perform the extracting of the contour, shifting the first control points to second control points, and when it is determined not to re-perform the extracting, determining the first curvilinear pattern layout as an OPCed layout. In the shifting, a first starting control point is shifted in a first direction different from a normal direction. After the shifting, the generating of the first curvilinear pattern layout is performed based on the second control points to generate a second curvilinear pattern layout.

### CROSS-REFERENCE TO RELATED APPLICATION

This application is based on and claims priority under 35 U.S.C. § 119 to Korean Patent Application No. 10-2023-0167151, filed on Nov. 27, 2023, in the Korean Intellectual Property Office, the disclosure of which is incorporated by reference herein in its entirety.

### BACKGROUND

The present disclosure relates to a method of manufacturing a mask, and more particularly, to an optical proximity correction (OPC) method and a method of manufacturing a mask by using the OPC method.

In a semiconductor process, in order to form a pattern on a semiconductor substrate such as a wafer, a photolithography process using a mask may be performed. The mask may be a pattern transfer material in which a pattern shape of an opaque material is formed on a transparent base material. In a process of manufacturing a mask, first, a circuit is designed, a layout of the circuit is designed, and then, design data obtained through OPC is transferred as mask tape-out (MTO) design data. Thereafter, mask data preparation (MDP) is performed based on the MTO design data, and an exposure process, etc. may be performed on a substrate for a mask.

### SUMMARY

The present disclosure provides an optical proximity correction (OPC) method in which an edge placement error (EPE) may be minimized up to a corner portion, and a method of manufacturing a mask by using the OPC method.

The objective of the technical idea of the present disclosure is not limited to the objective described above, and other problems could be clearly understood by a person skilled in the art from the description below.

According to an aspect of the present disclosure, an optical proximity correction (OPC) method includes generating a retarget curve line corresponding to a polygonal pattern layout of a target pattern, wherein two adjacent edges of the polygonal pattern layout are perpendicular to each other, generating a plurality of first control points on the retarget curve line, generating a first curvilinear pattern layout based on the plurality of first control points, extracting a contour of the target pattern through a simulation by inputting data of the first curvilinear pattern layout to an OPC model, calculating an edge placement error (EPE), which is a difference between the contour and an edge of the target pattern, determining whether to re-perform the extracting of the contour, when it is determined to re-perform the extracting of the contour, shifting the plurality of first control points to a plurality of second control points, and when it is determined not to re-perform the extracting of the contour, determining the first curvilinear pattern layout as an OPCed layout. In the shifting of the plurality of first control points to the plurality of second control points, a first starting control point, which is at least some of the plurality of first control points, is shifted in a first direction that is different from a normal direction relative to the first curvilinear pattern layout at the first starting control point. After the shifting of the plurality of first control points to the plurality of second control points, the generating of the first curvilinear pattern layout is performed based on the plurality of second control points to generate a second curvilinear pattern layout.

According to an aspect of the present disclosure, an optical proximity correction (OPC) method includes dividing an edge of a polygonal pattern layout of a target pattern into a plurality of segments, generating a plurality of initial control points on the edge of the polygonal pattern layout, generating a retarget curve line which is inscribed in the polygonal pattern layout, wherein the retarget curve line includes a round portion at a position corresponding to a vertex of the polygonal pattern layout, generating a plurality of first control points by shifting the plurality of initial control points onto the retarget curve line, generating a first curvilinear pattern layout based on the plurality of first control points, extracting a contour of the target pattern through a simulation by inputting data of the first curvilinear pattern layout to an OPC model, calculating an edge placement error (EPE), which is a difference between the contour and an edge of the target pattern, determining whether to re-perform the extracting of the contour, when it is determined to re-perform the extracting of the contour, shifting the plurality of first control points to a plurality of second control points, wherein a first starting control point among the plurality of first control points is shifted in a first direction that is different from a normal direction relative to the first curvilinear pattern layout at the first starting control point, and when it is determined not to re-perform the extracting of the contour, determining the first curvilinear pattern layout as an OPCed layout. After the shifting of the plurality of first control points to the plurality of second control points, the generating of the first curvilinear pattern layout is performed based on the plurality of second control points to generate a second curvilinear pattern layout.

According to an aspect of the present disclosure, a method of manufacturing a mask includes generating a retarget curve line corresponding to a polygonal pattern layout of a target pattern, wherein two adjacent edges of the polygonal pattern layout are perpendicular to each other, generating a plurality of first control points on the retarget curve line, generating a first curvilinear pattern layout based on the plurality of first control points, extracting a contour of the target pattern through a simulation by inputting data of the first curvilinear pattern layout to an optical proximity correction (OPC) model, calculating an edge placement error (EPE), which is a difference between the contour and an edge of the target pattern, determining whether to re-perform the extracting of the contour, when it is determined to re-perform the extracting of the contour, shifting the plurality of first control points to a plurality of second control points, when it is determined not to re-perform the extracting of the contour, determining the first curvilinear pattern layout as an OPCed layout, transferring data of the OPCed layout as mask tape-out (MTO) design data, preparing mask data based on the MTO design data, and performing exposure on a substrate based on the mask data to form a mask. In the shifting of the plurality of first control points to the plurality of second control points, a first starting control point, which is at least some of the plurality of first control points, is shifted in a first direction that is different from a normal direction relative to the first curvilinear pattern layout at the first starting control point. After the shifting of the plurality of first control points to the plurality of second control points, the generating of the first curvilinear pattern layout is performed based on the plurality of second control points to generate a second curvilinear pattern layout.

### BRIEF DESCRIPTION OF THE DRAWINGS

Embodiments of the present disclosure will be more clearly understood from the following detailed description taken in conjunction with the accompanying drawings in which:

FIG. 1 is a flowchart showing a process of an optical proximity correction (OPC) method, according to an embodiment;

FIG. 2 is a diagram illustrating the OPC method in FIG. 1;

FIGS. 3A and 3B are diagrams that show a principle of generating an initial control point used in an OPC method according to an embodiment;

FIGS. 4A and 4B are diagrams for describing settings of (+) and (−) directions of a first control point with respect to a first direction in the OPC method in FIG. 1;

FIGS. 5A to 5C are diagrams for describing selection of a first control point according to various rules and shifting of the first control point in a first direction in the OPC method in FIG. 1;

FIGS. 6A to 6C are diagrams showing curvilinear patterns (OPC form) generated by shifting a first control point in a first direction of two angles based on the OPC method in FIG. 1, with respect to a rectangular target pattern;

FIGS. 7A to 7D are diagrams showing curvilinear patterns (OPC form) generated by moving a first control point in a first direction of three angles based on the OPC method in FIG. 1, with respect to a rectangular target pattern, and a contour and an edge placement error (EPE) that are based on the curvilinear patterns; and

FIG. 8 is a flowchart showing a process of a method of manufacturing a mask by using an OPC method, according to an embodiment.

### DETAILED DESCRIPTION OF THE EMBODIMENTS

Hereinbelow, embodiments are described in detail with reference to the accompanying drawings. In the drawings, the same reference characters are used for the same elements, and redundant descriptions thereof are omitted.

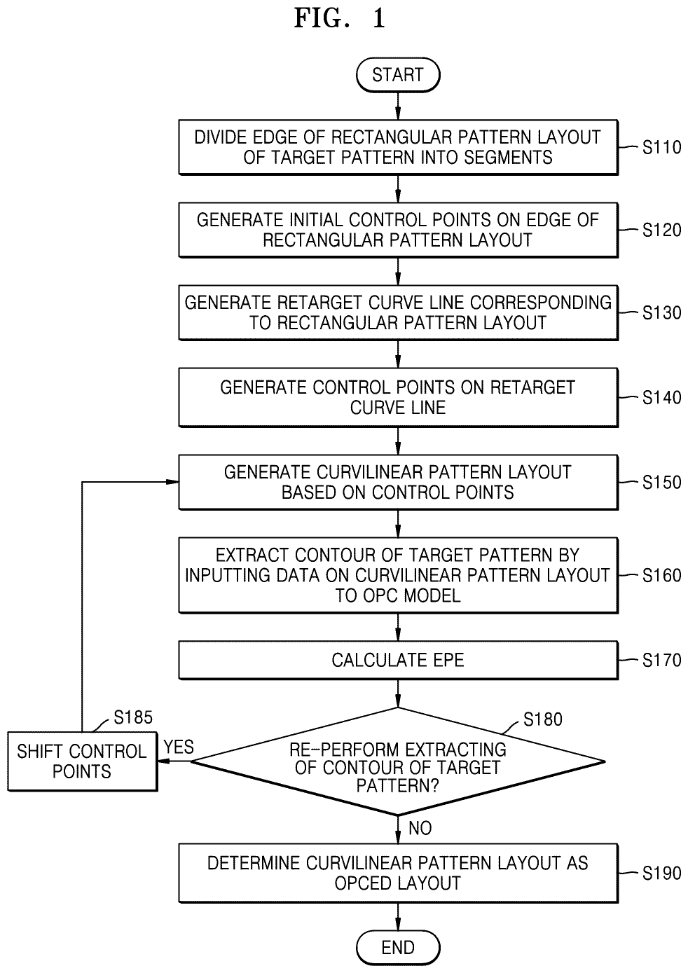

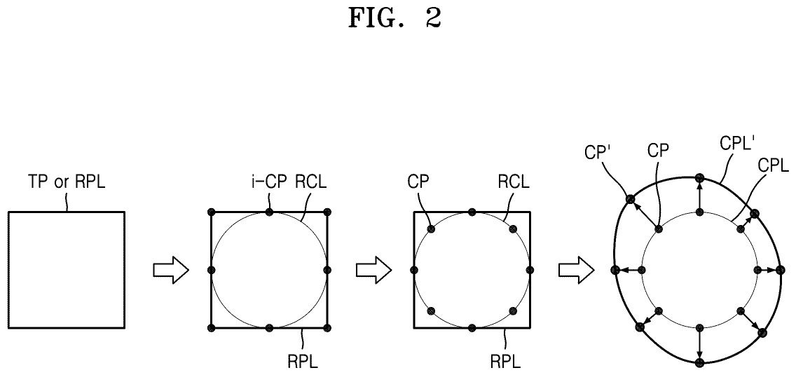

FIG. 1 is a flowchart showing a process of an optical proximity correction (OPC) method, according to an embodiment, and FIG. 2 shows diagrams illustrating the OPC method in FIG. 1.

Referring to FIGS. 1 and 2, in the OPC method according to an embodiment, first, an edge of a rectangular pattern layout of a target pattern is divided into segments, in operation S110. The target pattern may refer to a target pattern on a wafer, and the rectangular pattern layout may refer to a layout of a pattern that is on a mask corresponding to the target pattern. Here, the target pattern on a wafer may refer to a pattern to be formed on the wafer through an exposure process using a mask. For example, the pattern on the mask may be transferred to the wafer through an exposure process, so that a target pattern may be formed on the wafer. In an embodiment, the pattern on the mask may have a greater size than the target pattern on the wafer because the pattern on the mask is scaled down and projected on the wafer.

Due to the nature of an exposure process, a shape of the target pattern and a shape of a layout of the pattern on the mask may be different from each other. In an embodiment, from among layouts of the pattern on the mask, a layout of a pattern that includes only straight lines perpendicular to each other is referred to as a rectangular pattern layout.

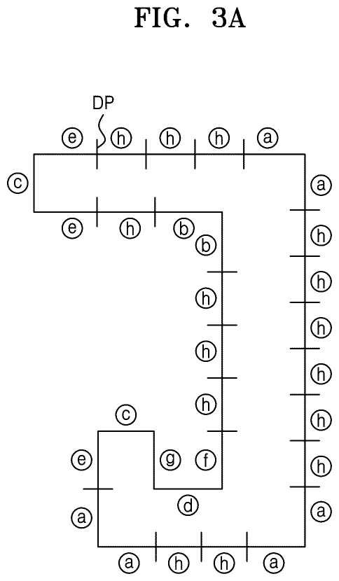

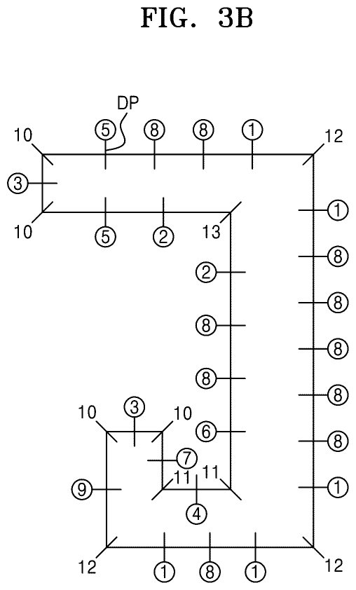

In FIG. 2, a leftmost pattern may correspond to a target pattern TP or a rectangular pattern layout RPL. The target pattern TP may be, for example, an after develop inspection (ADI) target pattern. The rectangular pattern layout RPL corresponding to the target pattern TP may be a layout of a pattern including only straight lines in which adjacent straight lines are perpendicular to each other. The present disclosure is not limited to the rectangular pattern layout RPL. In an embodiment, the target pattern TP may be a polygonal shape in which adjacent straight lines are perpendicular to each other, and a layout of a pattern corresponding to the target pattern TP may be a layout of a pattern having a polygonal shape in which adjacent straight lines are perpendicular to each other as shown in FIGS. 3A and 3B, for example. The layout of a polygonal shape pattern may be referred to as a polygonal pattern layout.

In a second pattern from the left shows a process of dividing an edge of the rectangular pattern layout RPL into segments. In an embodiment, the edge of the rectangular pattern layout RPL may correspond to a straight line connecting two adjacent vertices of the rectangular pattern layout. For example, a straight line between two adjacent dots on the rectangular pattern layout RPL may correspond to a segment. A segment may also be referred to as a fragment and may refer to a straight line corresponding to an edge of a layout, or data about the line. The edge of a layout may be divided into a plurality of segments according to a certain division rule. A segment length or a division rule for obtaining a segment may be set by a user that performs the OPC method.

In the OPC method, as a pattern is miniaturized, an optical proximity effect (OPE) due to influence between adjacent patterns occurs during an exposure process, and to overcome this, a layout of a pattern is corrected to suppress the occurrence of OPE. This OPC method is largely divided into two methods, i.e., a rule-based OPC method and a simulation-based, or model-based OPC method. The OPC method of the present disclosure may be, for example, the model-based OPC method. The model-based OPC method may be advantageous in terms of time and cost because only measurement results of representative patterns are used without the need to measure all of a large number of test patterns.

Thereafter, an initial control point i-CP may be generated at the edge of the rectangular pattern layout RPL, in operation S120. The initial control point i-CP may include a division point, which is a position at which a segment is divided, a vertex point, which is a vertex of the rectangular pattern layout RPL, and an additional points, which are on a segment between adjacent vertices. In the second pattern from the left in FIG. 2, the initial control point i-CP includes only a division point and a vertex point. The division point is located where a segment is divided, and a vertex point corresponds to a vertex of the rectangular pattern layout RPL. The initial control point i-CP is described in greater detail below with reference to FIGS. 3A and 3B.

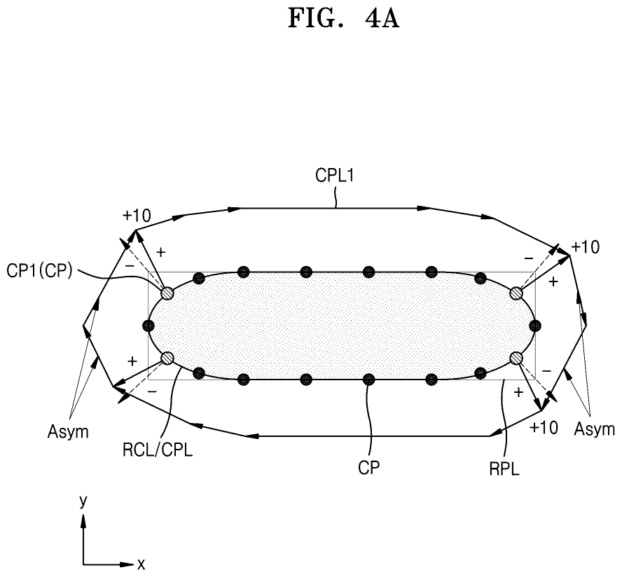

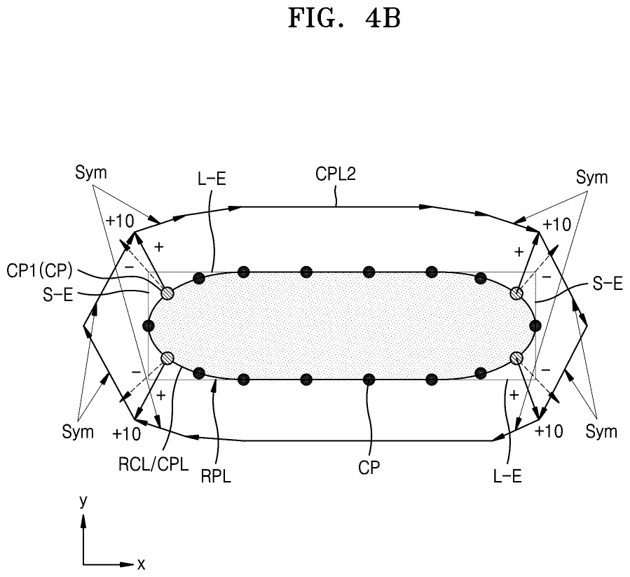

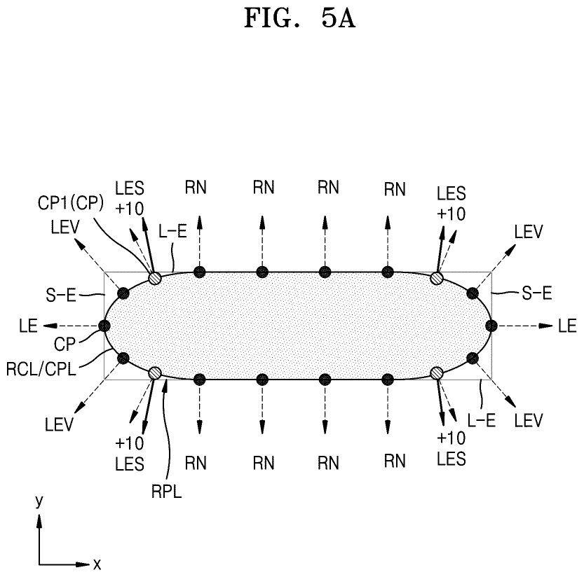

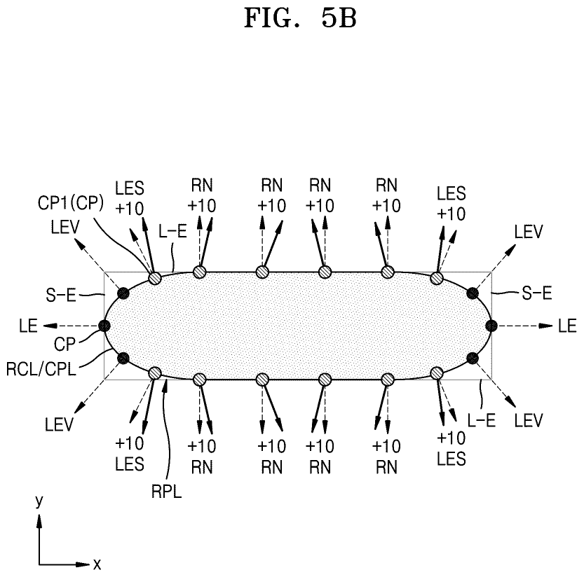

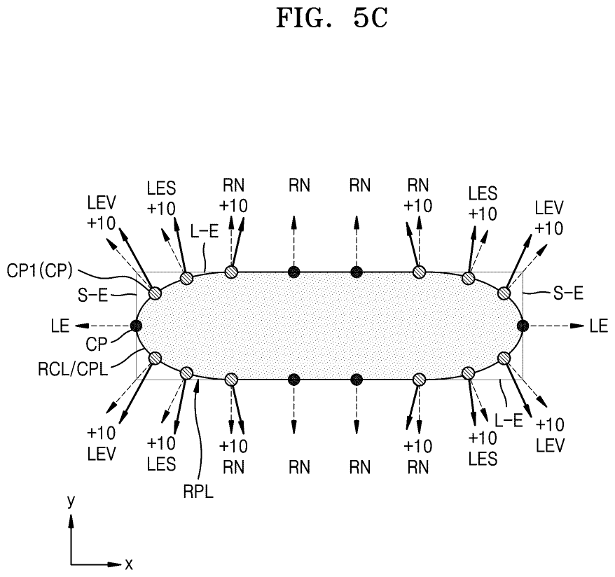

Next, a retarget curve line RCL corresponding to the target pattern TP or the rectangular pattern layout RPL is generated in operation S130. As shown in the second pattern from the left in FIG. 2, the retarget curve line RCL may have a circular shape that is inscribed in edges of the rectangular pattern layout RPL, for example, sides of a square. The retarget curve line RCL may be inscribed in the rectangular pattern layout RPL with a certain rule to correspond to a shape of the rectangular pattern layout RPL, and a portion of the retarget curve line RCL corresponding to a vertex of the rectangular pattern layout RPL may have a rounded shape. For example, when the rectangular pattern layout RPL is a square, the retarget curve line RCL may have a circular shape, as shown in the second pattern from the left in FIG. 2. When the rectangular pattern layout RPL is a rectangle that is elongated in one direction, the retarget curve line RCL may have an elliptical shape that is elongated in one direction, as shown in FIGS. 4A to 5C. When a retarget curve line RCL is inscribed in a polygonal pattern layout, the retarget curve line RCL may correspond to a closed loop having rounded shapes near vertices of the polygonal pattern layout.

A temporal order of operation S120 for generating the initial control point i-CP and operation S130 for generating the retarget curve line RCL may be changed. In an embodiment, first, operation S130 for generating the retarget curve line RCL may be performed, and then, operation S120 for generating the initial control point i-CP may be performed. In an embodiment, operation S120 for generating the initial control point i-CP and operation S130 for generating the retarget curve line RCL may be performed in parallel.

Thereafter, a control point CP may be generated on the retarget curve line RCL by shifting the initial control point i-CP to the retarget curve line RCL, in operation S140. The control point CP may be formed by shifting the initial control point i-CP in a normal direction with respect to the retarget curve line RCL. In a third pattern from the left in FIG. 2, it can be seen that the initial control points i-CP at the center of the sides of the rectangular pattern layout RPL become the control point CP on the rectangular pattern layout RPL, and the initial control points i-CP of the vertices of the rectangular pattern layout RPL are shifted to the retarget curve line RCL and become control points CP.

Next, a curvilinear pattern layout CPL may be generated based on the control points CP, in operation S150. In a rightmost pattern in FIG. 2, a small inner circle may correspond to an original curvilinear pattern layout CPL generated based on the control points CP. In addition, a large, closed curve outside the original curvilinear pattern layout CPL may correspond to a new curvilinear pattern layout CPL′ generated based on control points CP′ shifted from the control points CP on the original curvilinear layout out CPL.

The curvilinear pattern layouts CPL and CPL′ may be generated with a certain rule based on the control points CP and CP′. In the OPC method of the present disclosure, the curvilinear pattern layouts CPL and CPL′ may be generated in a form in which lines thereof do not cross each other while passing through both control points CP and CP′ without generating an additional point. For example, in the OPC method of the present disclosure, the curvilinear pattern layouts CPL and CPL′ may be generated by using a Catmull-Rom spline curve method. In the Catmull-Rom spline curve method, the control points CP may be continuously connected with each other to generate a curved closed loop of the curvilinear pattern layout CPL, and similarly, the control points CP′ may be continuously connected with each other to generate another curved closed loop of the curvilinear pattern layout CPL′. However, a method of generating the curvilinear pattern layouts CPL and CPL′ is not limited to the Catmull-Rom spline curve method.

In an embodiment, a shape of the original curvilinear pattern layout CPL may be substantially the same as that of the retarget curve line RCL, or there may be only a very slight difference. For example, there may be slight differences depending on the rules for generating the curvilinear pattern layout CPL based on the control points CP, but in most cases, the shape of the original curvilinear pattern layout CPL may be substantially the same as that of the retarget curve line RCL. Accordingly, the original curvilinear pattern layout CPL of the rightmost pattern in FIG. 2 may have substantially the same circular shape as the retarget curve line RCL shown in the second pattern from the right in FIG. 2.

Thereafter, data about the curvilinear pattern layout may be input to an OPC model, so as to extract a contour of the target pattern, in operation S160. Here, the data about the curvilinear pattern layout CPL may include data about edges of the curvilinear pattern layout CPL. Depending on embodiments, a contour of the retarget curve line may be extracted instead of the contour of the target pattern. In an embodiment, a contour of the retarget curve line may be extracted as a contour of the target pattern.

The OPC model is a simulation model for extracting the contour of the target pattern, and various basic data may be input to the OPC model as input data. Here, the basic data may include mask data, for example, data about the edges of the curvilinear pattern layout CPL. In an embodiment, the basic data includes information data such as thickness, refractive index, and dielectric constant of photo-resist (PR), and may include source map data for a shape of an illumination system. However, the basic data is not limited to the data described above. In an embodiment, the mask data included in the basic data may include not only data about the edges of the curvilinear pattern layout CPL but also various information about shapes or positions of the target pattern and the retarget curve line.

The contour of the target pattern is a result of simulation using the OPC model and may correspond to a shape of a target pattern formed on a wafer during an exposure process using a mask. Accordingly, the purpose of the OPC method of the present disclosure may be to make the contour as similar as possible to the shape of the target pattern. In FIG. 2, a process of extracting the contour of the target pattern and an EPE calculation process are omitted and are not shown.

After the contour of the target pattern is extracted, an EPE is calculated, in operation S170. EPE may refer to a difference between the edge of the target pattern and the contour extracted from the previous simulation using the OPC model.

EPE may calculated by Equation (1) shown below.

$$EPE = target pattern - contour \qquad Equation ( 1 )$$

EPE may simply refer to the difference between the edge of the target pattern and the contour. When the EPE is large, the difference between the contour and the target pattern is large, which may mean that the curvilinear pattern layout CPL is not suitable for forming the target pattern. Accordingly, in order to implement a curvilinear pattern layout CPL suitable for forming the target pattern, a process of changing the curvilinear pattern layout CPL and lowering the EPE may be repeated until the EPE has a set reference value or less. The EPE is a distance calculated from evaluation points preset in the target pattern and may be obtained by subtracting the edge of the target pattern of the evaluation points by a contour portion corresponding to the evaluation points of the target pattern.

After calculating the EPE, it is determined whether to re-perform operation S160 for extracting the contour of the target pattern, in operation S180. For example, it may be determined whether to re-perform operation S160 for extracting the contour of the target pattern, depending on whether the calculated EPE exceeds the set reference value. For example, when the calculated EPE exceeds the reference value, it may be determined to re-perform operation S160 for extracting the contour of the target pattern, and when the calculated EPE is the reference value or less, it may be determined not to re-perform operation S160 for extracting the contour of the target pattern.

In an embodiment, it may be determined as to whether to re-perform operation S160 for extracting the contour of the target pattern by comparing the number of times a simulation using the OPC model is performed with a set reference number. For example, when the number of times the simulation using the OPC model is performed is less than the reference number, it may be determined to re-perform operation S160 for extracting the contour of the target pattern, and when the number of times the simulation using the OPC model is performed is equal to the reference number, it is determined not to re-perform operation S160 for extracting the contour of the target pattern. Here, the reference number may generally be set based on an average number or maximum number of times the EPE reaches the reference value through simulation using an OPC model. In an embodiment, the number of times the simulation using the OPC model is performed may be substantially equal to the number of times operation S160 for extracting the contour of the target pattern.

When it is determined to re-perform operation S160 for extracting the contour of the target pattern (Yes), the control points CP may be shifted in operation S185. The shifting of the control points CP may be performed by calculating displacement of each of the control points CP and shifting the control points CP in a set direction by the calculated displacement. The displacement of the control points CP may be obtained for each of the control points CP, so that an average of the EPEs calculated from the evaluation points is minimized. As can be understood from the rightmost pattern in FIG. 2, the control point CP on the curvilinear pattern layout CPL, which is a small circle, may be shifted to the outside, so that a new control point CP′ and a new curvilinear pattern layout CPL′ corresponding thereto may be generated.

In the OPC of the present disclosure, the shifting direction of most control points CP may be a normal direction relative to the curvilinear pattern layout CPL. However, first control points, which are at least some of the control points CP, may be shifted in a first direction that is different from the normal direction. The first control points and the first direction are described in greater detail in descriptions of FIGS. 4A and 4B. Selection of the first control points is described in greater detail in descriptions of FIGS. 5A to 5C.

Next, the process moves to operation S150 for generating a curvilinear pattern layout CPL. In operation S150 for generating the curvilinear pattern layout CPL, a new curvilinear pattern layout CPL′ may be generated based on the new control point CP′. The shifting of the control point CP to the new control point CP′ may change the curvilinear pattern layout CPL to the new curvilinear pattern layout CPL′.

Thereafter, operation S160 for extracting the contour of the target pattern, operation S170 for calculating an EPE, and operation S180 for determining whether to re-perform the operation of extracting the contour of the target pattern may be performed. Such operations may be repeated until the EPE becomes a set reference value or less. In an embodiment, the operations may be repeated until the number of times a simulation using an OPC model is performed becomes equal to the set reference number. In operation S160 for extracting the contour of the target pattern, data about the new curvilinear pattern layout CPL′ may be input to the OPC model.

When it is determined not to re-perform operation S160 for extracting the contour of the target pattern (No), the curvilinear pattern layouts CPL and CPL′ may be determined as an OPCed layout, in operation S190. The OPCed layout may refer to a final pattern layout that is transferred on the mask for which performance of OPC has been completed. The OPCed layout may have a curvilinear shape with a minimized EPE by repeating several times operation S185 for shifting the control points CP and CP′ and operation S150 for generating the curvilinear pattern layouts CPL and CPL′.

In a first simulation using the OPC model, the EPE obtained from contour extraction of the target pattern and resulting EPE calculation may deviate significantly from the reference value. Accordingly, after performing tens of simulations using the OPC model, it may be determined not to re-perform operation S160 for extracting the contour of the target pattern. As a result, an OPCed layout may be obtained through a process of shifting the control points CP and CP′ a plurality of times and generating the curvilinear pattern layout CPL′ a plurality of times.

In the OPC method of the present disclosure, an edge of a rectangular pattern layout of a target pattern is divided into segments, and an initial control point is generated at the edge of the rectangular pattern layout and shifted onto a retarget curve line, so as to generate control points. Thereafter, a curvilinear pattern layout is generated based on the control points, a contour is extracted through a simulation using an OPC model, an EPE is calculated, and the simulation using the OPC model is repeated according to certain criteria, so as to generate an OPCed layout in which the EPE may be minimized. In addition, in the OPC method of the present disclosure, when the OPCed layout in which the EPE may be minimized is generated, an excellent mask capable of optimally forming a target pattern on a wafer may be manufactured.

In the OPC method of the present disclosure employing a point-based OPC method, freedom of the OPCed layout may be significantly improved compared to a segment-based OPC method. In other words, control points are generated after dividing an edge of the rectangular pattern layout into segments, and the control points are shifted instead of the segments, to generate a curvilinear pattern layout. As described above, in the OPC method of the present disclosure, control points are used instead of segments, to generate a freer curvilinear pattern layout. In the OPC method of the present disclosure, when a shifting direction of the control points is changed to various directions rather than being limited to the normal direction, free-angle OPC may be implemented. For example, by moving a shifting direction with respect to a first control point, which is at least some of the control points, differently from the normal direction, a curvilinear pattern layout in which the EPE may be minimized, that is, an OPCed layout, may be generated.

FIGS. 3A and 3B are diagrams that show a principle of generating an initial control point used in an OPC method of the present disclosure. Details described above with reference to FIGS. 1 and 2 are briefly described or omitted.

Referring to FIGS. 3A and 3B, in FIG. 3A, segments [symbol] to [symbol] that are generated after dividing edges of a rectangular pattern layout at a division point DP are shown. In the segment-based OPC method, a subsequent OPC process may be performed by using the segments [symbol] to [symbol] . In the segment-based OPC method, there may be restrictions in angle and distance in the movement of the segments [symbol] to [symbol] in particular, around multiple corners which are disposed in a small area in a target pattern. In an embodiment, the segments [symbol] to [symbol] may be classified into, by location, an out-corner segment [symbol] , an in-corner segment [symbol] , a line-end segment [symbol] , a space-end segment [symbol] , a line-end-side segment [symbol] , a space-end-side segment [symbol] , a single segment, [symbol] a run segment [symbol] , etc. FIGS. 3A and 3B shows a polygonal shape pattern, but for the convenience of description, such polygonal shape pattern may be referred to a rectangular pattern layout.

In FIG. 3B, initial control points i-CP that are generated after dividing the edges of the rectangular pattern layout at the division point DP are shown. In the OPC method of the present disclosure, a subsequent OPC process may be performed by using an initial control point instead of a segment. The initial control points i-CP may be classified into three types. For example, the initial control points i-CP may include initial-control points [symbol] , and [symbol] corresponding to division points, initial-control points 10 to 13 corresponding vertex points, and initial-control points [symbol] , and [symbol] corresponding to additional points. Here, the division points may be division points for segments, the vertex points may be positions of vertices of a rectangular pattern layout (i.e., a polygonal pattern layout), and the additional points may be positioned on a segment between adjacent vertices.

Similar to segments, the initial-control points [symbol] , and [symbol] corresponding to the division points may include an out-corner point [symbol] , an in-corner point [symbol] , a line-end-side point [symbol] , a space-end-side point [symbol] , a run point [symbol] , other points [symbol] , etc. The initial-control points 10 to 13 corresponding to the vertex points may include a line-end vertex point 10, a space-end vertex point 11, an out-vertex point 12, an in-vertex point 13, etc. In the initial-control points [symbol] , [symbol] , and [symbol] corresponding to the additional points may include, due to similarly positioned segments, a line-end point [symbol] , a space-end point [symbol] , and a single point [symbol] , etc. Although not shown in FIG. 3B, a jog vertex point indicating a fine protrusion or fine recess portion present in a section of the run points [symbol] may be included in the initial control point i-CP.

In the OPC method of the present disclosure, the names of the initial control points i-CP are not limited to the names as described above. For example, depending on a shape of the rectangular pattern layout (i.e., the polygonal pattern layout), the name of each of the initial control points i-CP may be variously changed. For example, in FIG. 5A, in a rectangular pattern layout that is elongated in the x direction, the initial control points i-CP may include line-end points LE at centers of short edges at opposite sides in the x direction, run points RN on elongated edge lines that are opposite to each other in the y direction, a line-end vertex point LEV at vertices, and a line-end-side point LES on a line of a long edge adjacent to the vertices. The initial control point i-CP may be shifted onto the retarget curve line RCL and may become the control points CP on the retarget curve line RCL. The names of the control points CP may remain the same as the names of the initial control point i-CP.

FIGS. 4A and 4B are diagrams for describing settings of (+) and (−) directions of a first control point CP1 with respect to a first direction in the OPC method in FIG. 1. Details described above with reference to FIGS. 1 to 3B are briefly described or omitted. The (+) direction may be referred to as a positive direction, and the (−) direction may be referred to as a negative direction.

In FIGS. 4A and 4B, a rectangle that is elongated in the x direction may be the rectangular pattern layout RPL, an ellipse that is inscribed in the rectangular pattern layout RPL and elongated in the x direction may be the retarget curve line RCL or the original curvilinear pattern layout CPL, and dots on the curvilinear pattern layout CPL may correspond to the control points CP. An outer line may correspond to the new curvilinear pattern layouts CPL1 and CPL2 that are generated by the shifting of the control points CP. The dotted arrows may correspond to the normal direction with respect to the curvilinear pattern layout CPL at a corresponding control point.

In the OPC method of the present disclosure, some of the control points CP may be selected as the first control point CP1, and the first control points CP1 may be shifted in a first direction that is different from the normal. Here, the first direction may correspond to a direction in which a moving angle (i.e., a rotation angle) in the (+) or (−) direction is added to the normal direction.

Referring to FIG. 4A, FIG. 4A shows a shape of, when the (+) direction of the first direction is set to a clockwise direction and the (−) direction is set to a counterclockwise direction, generating a curvilinear pattern layout CPL1 by selecting the line-end vertex points LEV as the first control points CP1 and shifting the first control points CP1 in the first direction of (+) 10° rotated from the normal direction. As described above, when the (+) and (−) directions of the first direction are respectively set to the clockwise and counterclockwise directions, as indicated by the arrow of Asym, edges of the generated curvilinear pattern layout CPL1 may are arranged without maintaining top-bottom and left-right symmetry. For example, the edges of the generated curvilinear pattern layout CPL1 may be asymmetric. In generating the curvilinear pattern layout CPL1, the remaining control points CP except the first control points CP1 may be shifted in the normal direction.

Referring to FIG. 4B, when setting the (+) direction of the first direction to rotating of a normal direction toward a long-edge L-E side of the rectangular pattern layout RPL and setting the (−) direction of the first direction to rotating of a normal direction toward a short-edge S-E of the rectangular pattern layout RPL, a curvilinear pattern layout CPL2 is generated by selecting the line-end vertex points LEV as the first control points CP1 and shifting the first control points CP1 in a first direction of (+) 10° rotated toward the long-edge L-E side. As described above, when setting the (+) and (−) directions of the first direction by using the long-edge L-E and the short-edge S-E of the rectangular pattern layout RPL, as indicated by the arrows of Sym, edges of the generated curvilinear pattern layout CPL2 may maintain top-bottom and left-right symmetry. The remaining control points CP except the first control points CP1 may be shifted in the normal direction.

In the OPC method of the present disclosure, the (+) and (−) directions of the first direction of the first control points CP1 may be set so that the shape of the curvilinear pattern layout CPL2 may maintain top-bottom and left-right symmetry. For example, in the OPC method of the present disclosure, the (+) direction of the first direction may be set as rotating of a normal direction toward the long-edge L-E side of the rectangular pattern layout RPL, and the (−) direction of the first direction may be set as rotating of a normal direction toward the short-edge S-E of the rectangular pattern layout RPL, or vice versa.

FIGS. 5A to 5C are diagrams for describing selection of a first control point CP1 according to various rules and shifting of the first control point CP1 in a first direction in the OPC method in FIG. 1. Details described above with reference to FIGS. 1 to 4B are briefly described or omitted.

In FIGS. 5A to 5C, a rectangle that is elongated in the x direction may be the rectangular pattern layout RPL, an ellipse that is inscribed in the rectangular pattern layout RPL and elongated in the x direction may be the retarget curve line RCL or the original curvilinear pattern layout CPL, and dots on the curvilinear pattern layout CPL may correspond to the control points CP. Solid or dotted arrows may correspond to directions in which the control points CP are shifted to generate a new curvilinear pattern layout.

Referring to FIGS. 5A to 5C, in the OPC method of the present disclosure, a method of selecting the first control point CP1 based on types of the control points CP is shown. For example, in FIG. 5A, the line-end-side point LES may be selected as the first control point CP1, and the first control point CP1 may be shifted in the first direction of (+) 10° rotated toward the long-edge L-E, so as to generate a curvilinear pattern layout. As described above, the (+) and (−) directions of the first direction may be set by using the long-edge L-E and the short-edge S-E of the rectangular pattern layout RPL. In FIG. 5A, the first directions of the first control points CP1 are indicated by solid arrows. The remaining control points CP except the first control point CP1 may be shifted in the normal direction, which is indicated by dotted arrows.

In FIG. 5B, the lineendside point LES and the run point RN may be selected as the first control points CP1, and the first control points CP1 may be shifted in the first direction of (+) 10° rotated toward the long-edge L-E, so as to generate a curvilinear pattern layout. As described above, the (+) and (−) directions of the first direction may be set by using the long-edge L-E and the short-edge S-E of the rectangular pattern layout RPL. Even in FIG. 5B, the first directions of the first control points CP1 are indicated by solid arrows. The remaining control points CP except the first control point CP1 may be shifted in the normal direction, which is indicated by dotted arrows.

In FIGS. 5A and 5B, a method of selecting the line-end-side point LES and/or the run point RN as the first control point CP1 is illustrated. However, in the OPC method of the present disclosure, a method of selecting the first control point CP1 based on the types of the control points CP is not limited thereto. For example, the first control point CP1 may be selected through various combinations of the line-end points LE, the run point RN, the line-end vertex point LEV, and the line-end-side point LES.

In the OPC method of the present disclosure, a method of selecting the first control point CP1 is not limited to a selection method based on the types of the control points CP. For example, the method of selecting the first control point CP1 may include a selection method based on a length between a current control point and a previous control point or the current control point and a next control point adjacent thereto, or a selection method using an angle of the original normal direction.

In the selection method based on the length between the current control point and the previous control point or next control point adjacent thereto, first, the previous control point, the current control point, and the next control point may be defined in the clockwise direction. For example, the previous control point, the current control point, and the next control point may be adjacent to each other in the clockwise direction. In other words, a control point that is adjacent to the current control point in the clockwise direction may correspond to the next control point, and a control point that is adjacent in the counterclockwise direction may correspond to the previous control point.

The selection method based on the length between the current control point and the previous control point may be a method of selecting the current control point as the first control point CP1 when the length between the current control point and the previous control point is a set reference length or less or within a set range. The selection method based on the length between the current control point and the next control point may be a method of selecting the current control point as the first control point CP1 when the length between the current control point and the next control point is a set reference length or less or within a set range.

In the selection method using an angle of the original normal direction, the original normal directions of the original control points CP on the retarget curve line RCL or the original curvilinear pattern layout CPL may be determined in units of 45° relative to a reference line. In an embodiment, the reference line may be a straight line extending along the y direction. For example, the run points RN of the upper and lower long-edges L-E may have an original normal direction of 0° and 180° with reference to the reference line. The line-end points LE of the left and right short-edges S-E may have an original normal direction of 270° and 90° with reference to the reference line. The line-end vertex points LEV corresponding to four vertices may have an original normal direction of 45°, 135°, 225°, and 315° clockwise from the upper right. Accordingly, the first control point CP1 may be selected by selecting an angle of the original normal direction. For example, when 45°, 135°, 225°, and 315° are selected as the angles of the original normal direction, the line-end vertex point LEV may be selected as the first control point CP1. In an embodiment, the angle of the normal direction may be defined in a clockwise or a counter-clockwise direction.

In the OPC method of the present disclosure, a method of selecting the first control point CP1 may include a combination of the methods described above. For example, the first control point CP1 may be selected based on a combination of at least two of the types of control points, the length between a current control point and the previous control point adjacent thereto, the length between the current control point and the next control point adjacent thereto, and the angle of the original normal direction.

Furthermore, in the OPC method of the present disclosure, in a method of selecting the first control point CP1, control points around the control point with a relatively large EPE may be grouped and selected as the first control point CP1. For example, in FIG. 5C, when an EPE is large at the lineendside point LES, the control points CP before and after the line-end-side point LES, that is, the line-end vertex point LEV, and the outermost run point RN may be grouped together with the line-end-side point LES and selected as the first control point CP1.

Although various methods of selecting the first control point CP1 are described above, in the OPC method of the present disclosure, a method of selecting the first control point CP1 is not limited to the methods described above. For example, in the OPC method of the present disclosure, in order to minimize the EPE, more diverse methods for selecting the first control point CP1 may be employed.

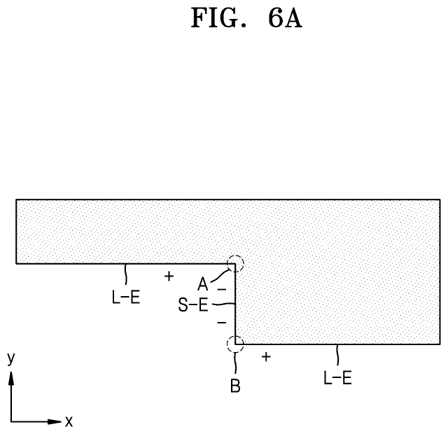

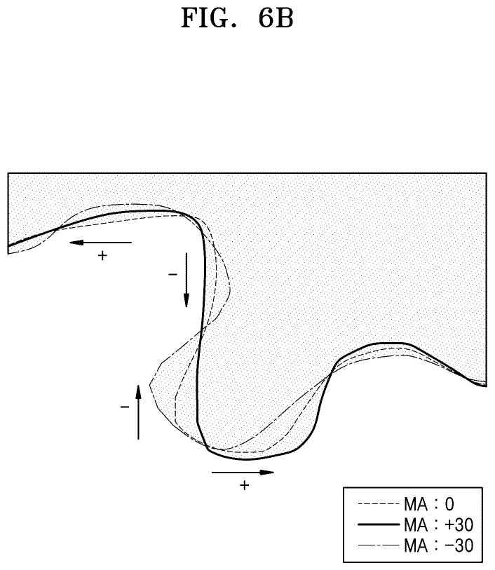

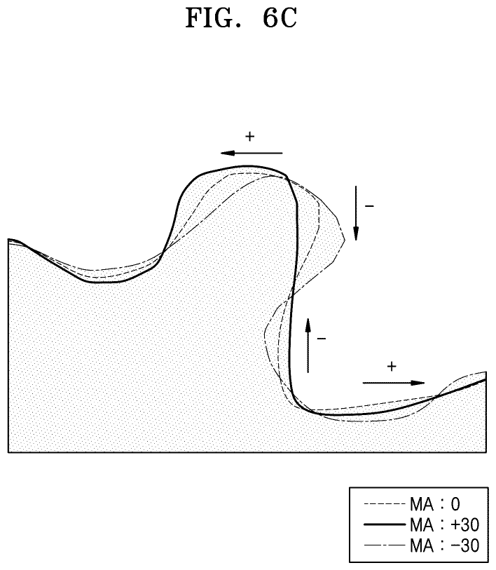

FIGS. 6A to 6C are diagrams showing curvilinear patterns (OPC form) generated by shifting a first control point in a first direction of two angles based on the OPC method in FIG. 1, with respect to a rectangular target pattern. Details described above with reference to FIGS. 1 to 5C are briefly described or omitted.

Referring to FIGS. 6A to 6C, FIG. 6A shows a target pattern, or a rectangular pattern layout corresponding thereto. With respect to a first vertex A of a concave portion, an edge line extending in the x direction may correspond to the long-edge L-E, and an edge line extending in the y direction may correspond to the short-edge S-E. Accordingly, rotation of a normal line toward the long-edge L-E side is the (+) direction of the first direction, and rotation of a normal line toward the short-edge S-E side is the (−) direction of the first direction. With respect to a second vertex B of a lower left side, an edge line extending in the x direction may correspond to the long-edge L-E, and an edge line extending in the y direction may correspond to the short-edge S-E. Accordingly, rotation of a normal line toward the long-edge L-E side is the (+) direction of the first direction, and rotation of a normal line toward the short-edge S-E side is the (−) direction of the first direction.

FIGS. 6B and 6C show curvilinear pattern layouts generated by shifting a first control point in a first direction having moving angles MA of 0°, (+) 30°, and (−) 30°. FIG. 6B show curvilinear pattern layouts with respect to the rectangular pattern layout of FIG. 6A, and FIG. 6C are curvilinear pattern layouts with respect to a rectangular pattern layout that is point symmetrical to the rectangular pattern layout in FIG. 6A. It can be seen that the curvilinear pattern layouts change significantly by applying the first control point according to the moving angle MA. In addition, based on setting of the (+) and (−) directions of the first direction based on the long-edge L-E and the short-edge S-E of the rectangular pattern layout, it can be seen that the curvilinear pattern layouts in FIG. 6C are generated in a symmetrical form with the curvilinear pattern layouts in FIG. 6B. Here, the first control point in the first direction having the moving angle MA of 0° corresponds to a control point in the original normal direction.

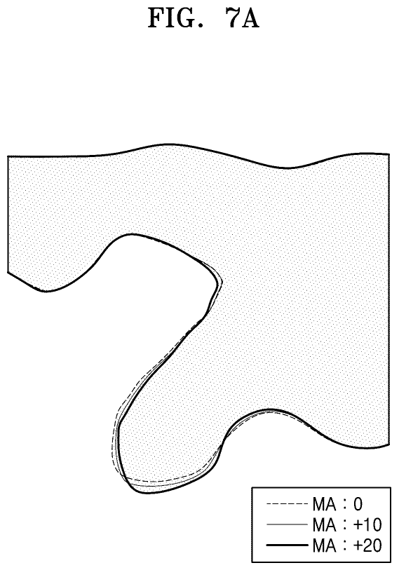

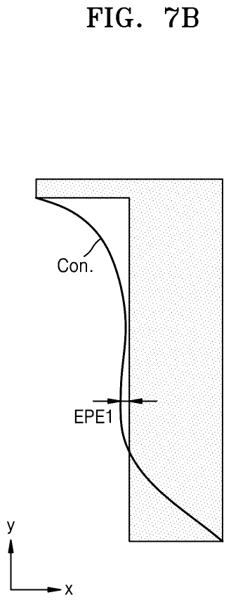

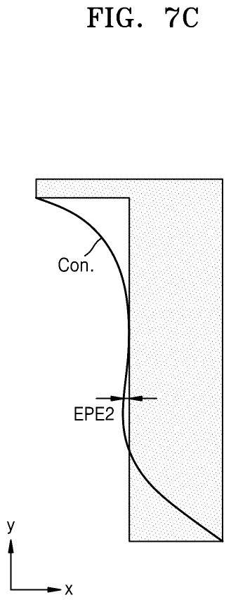

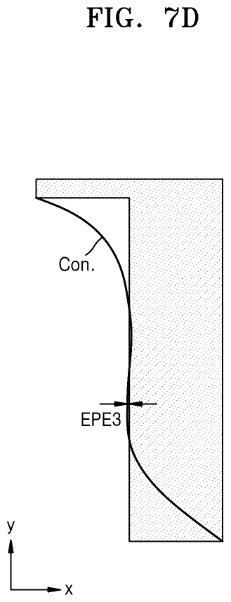

FIGS. 7A to 7D are diagrams showing curvilinear patterns (OPC form) generated by moving a first control point in a first direction of three angles based on the OPC method in FIG. 1, with respect to a rectangular target pattern, and a contour and an EPE that are based on the curvilinear patterns. Details described above with reference to FIGS. 1 to 6C are briefly described or omitted.

Referring to FIGS. 7A to 7D, FIG. 7A shows curvilinear pattern layouts that are generated by shifting the first control point in the first direction having the moving angles MA of 0°, (+) 10°, and (+) 20°, with respect to the target pattern in FIG. 6A or the rectangular pattern layout corresponding thereto. By reducing the change in the moving angle MA, it can be seen that the change in the curvilinear pattern layouts decreases compared to the curvilinear pattern layouts in FIG. 6B.

FIGS. 7B to 7C show an embodiment in which a contour Con. of a target pattern is extracted by applying the curvilinear pattern layouts corresponding to the moving angles MA of 0°, (+) 10°, and (+) 20° to the OPC model, and an EPE is calculated. In the curvilinear pattern layout corresponding to the moving angle MA of 0° in FIG. 7B, the EPE EPE1 may be calculated to be about 0.63 nm, in the curvilinear pattern layout corresponding to the moving angle MA of (+) 10° in FIG. 7C, an EPE EPE2 may be calculated to be about 0.4 nm, and in the curvilinear pattern layout corresponding to the moving angle MA of (+) 20° in FIG. 7D, an EPE EPE3 may be calculated to be about 0.1 nm. Thus, in the OPC method of the present disclosure, it can be seen that the EPE may be reduced significantly compared to the OPC method using a control point in the original normal direction.

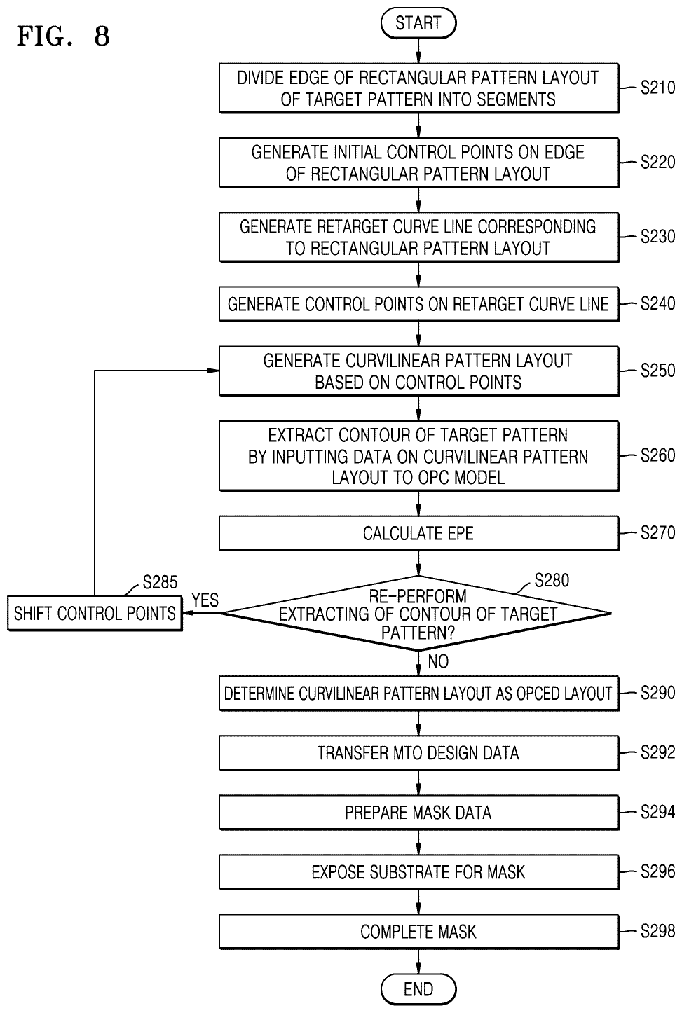

FIG. 8 is a flowchart showing a process of a method of manufacturing a mask by using an OPC method, according to an embodiment. The description is provided with reference to FIGS. 1 and 8 together, and details described above in the description of FIG. 7D are briefly described or omitted.

Referring to FIG. 8, in the method of manufacturing a mask by using the OPC method (hereinafter, referred to as the “mask manufacturing method”), first, an OPC method is performed. The OPC method may include operation S210 for dividing an edge of a rectangular pattern layout of a target pattern into segments to operation S290 of determining a curvilinear pattern layout as an OPCed layout. In the mask manufacturing method of the present disclosure, the OPC method may include, for example, the OPC method in FIG. 1. For example, operation S210 for dividing an edge of a rectangular pattern layout of a target pattern into segments to operation S290 for determining a curvilinear pattern layout as an OPCed layout may correspond to operation S110 for dividing an edge of a rectangular pattern layout of a target pattern to operation S190 for determining a curvilinear pattern layout as an OPCed layout, of the OPC method in FIG. 1. Accordingly, in the mask manufacturing method of the present disclosure, detailed descriptions of the respective operations S210 to S290 of the OPC method are omitted.

After the OPC method is performed, mask tape-out (MTO) design data is transferred to a mask production team, in operation S292. In general, MTO may refer to handing over data on a pattern layout on a final mask obtained through the OPC method to the mask production team to request mask production. Accordingly, in the mask manufacturing method of the present disclosure, the MTO design data may be substantially the same as the data for the OPCed layout obtained through the OPC method. This MTO design data may have a graphic data format used in Electronic design automation (EDA) software, etc. For example, the MTO design data may have a data format such as Graphic Data System II (GDS2), Open Artwork System Interchange Standard (OASIS), etc.

Thereafter, mask data preparation (MDP) is performed in operation S294. The MDP may include, for example, i) format conversion, called fracturing, ii) augmentation such as barcodes for mechanical reading, standard mask patterns for inspection, and job decks, and iii) verification of automatic and manual methods. Here, the job-deck may refer to creating a text file regarding a series of instructions such as arrangement information of multiple mask files, standard dose, and exposure speed or method.

The format conversion, that is, fracturing, may refer to a process of dividing MTO design data for each area and changing the divided MTO design data into a format for an electronic beam exposure machine. Fracturing may include, for example, data manipulation such as scaling, sizing of data, rotation of data, reflecting patterns, and inverting colors. In the conversion process through fracturing, data may be corrected for numerous systematic errors that may occur somewhere during the transfer from design data to an image on the wafer.

The data correction process for the systematic errors is called mask process correction (MPC) and may include, for example, line width adjustment called critical dimension (CD) adjustment and an operation to increase pattern arrangement precision. Thus, fracturing may contribute to improving the quality of the final mask and may also be a process that is performed in advance for MPC. Here, the systematic errors may be caused by distortions occurring in the exposure process, a mask development and etching process, and a wafer imaging process.

The Mask data preparation (MDP) may include MPC. As described above, the MPC refers to a process of correcting errors that occur during the exposure process, that is, system errors. Here, the exposure process may be an overall concept that includes electronic beam writing, development, etching, baking, etc. In addition, data processing may be performed before the exposure process. Data processing is a preprocessing process for mask data and may include grammar check for mask data, exposure time prediction, etc.

After MDP, a substrate for a mask is exposed based on the mask data. Here, the exposure may refer to, for example, electron beam writing. Here, electron beam writing may be performed, for example, through a gray writing method using a multi-beam mask writer (MBMW). In addition, electron beam writing may be performed by using a variable shape beam (VSB) exposure machine.

After the MDP operation is completed, a process of converting the mask data into pixel data may be performed before the exposure process. The pixel data is data directly used for actual exposure and may include data on a shape to be exposed and data on a dose assigned to each shape. Here, the data on the shape may be bit-map data obtained by converting shape data, which is vector data, through rasterization or the like.

After the exposure process, a mask is completed by performing a series of processes, in operation S298. The series of processes may include, for example, development, etching, and cleaning. In addition, the series of processes for manufacturing a mask may include a metrology process, defect inspection, or a defect repair process. Furthermore, the series of processes for manufacturing a mask may include a pellicle application process. Here, the pellicle application process may refer to a process of, when it is identified that there are no contaminant particles or chemical stains through final cleaning and inspection, attaching a pellicle to a mask surface to protect the mask from subsequent contamination during delivery and during an available life of the mask.

While the present disclosure has been particularly shown and described with reference to embodiments thereof, it will be understood that various changes in form and details may be made therein without departing from the spirit and scope of the following claims.

What is claimed is:

1. An optical proximity correction (OPC) method comprising:
generating a retarget curve line corresponding to a polygonal pattern layout of a target pattern, wherein two adjacent edges of the polygonal pattern layout are perpendicular to each other;
generating a plurality of first control points on the retarget curve line;
generating a first curvilinear pattern layout based on the plurality of first control points;
extracting a contour of the target pattern through a simulation by inputting data of the first curvilinear pattern layout to an OPC model;
calculating an edge placement error (EPE), which is a difference between the contour and an edge of the target pattern;
determining whether to re-perform the extracting of the contour;
when it is determined to re-perform the extracting of the contour, shifting the plurality of first control points to a plurality of second control points; and
when it is determined not to re-perform the extracting of the contour, determining the first curvilinear pattern layout as an OPCed layout,
wherein, in the shifting of the plurality of first control points to the plurality of second control points, a first starting control point, which is at least some of the plurality of first control points, is shifted in a first direction that is different from a normal direction relative to the first curvilinear pattern layout at the first starting control point, and
wherein after the shifting of the plurality of first control points to the plurality of second control points, the generating of the first curvilinear pattern layout is performed based on the plurality of second control points to generate a second curvilinear pattern layout.

2. The OPC method of claim 1,
wherein the first starting control point is preset according to a certain rule before the shifting of the plurality of first control points to the plurality of second control points, and
wherein the first direction corresponds to a direction obtained by rotating the normal direction in a positive direction or a negative direction so that the second curvilinear pattern layout maintains top-bottom and left-right symmetry.

3. The OPC method of claim 2,
wherein the first direction corresponds to a direction obtained by rotating the normal direction by a moving angle in the positive direction or the negative direction, and
wherein with respect to the first starting control point, the positive direction is set to a rotation direction of the normal direction toward one of a long-edge line of the polygonal pattern layout and a short-edge line, directly connected to the long-edge line, of the polygonal pattern layout, and the negative direction is set to a rotation direction of the normal direction toward the other of the long-edge line and the short-edge line.

4. The OPC method of claim 2,
wherein the control points are classified into various types according to a shape of the polygonal pattern layout, and
wherein the first starting control point is selected based on types of the plurality of first control points.

5. The OPC method of claim 2,
wherein a previous control point, a current control point, and a next control point are adjacent to each other in a clockwise direction among the plurality of first control points, and
wherein the first starting control point is selected based on a length between the current control point and the previous control point or a length between the current control point and the next control point.

6. The OPC method of claim 2,
wherein the first starting control point is selected based on an angle of the normal direction relative to a reference line.

7. The OPC method of claim 2,
wherein the control points are classified into various types to a shape of the polygonal pattern layout,
wherein a previous control point, a current control point, and a next control point are adjacent to each other in a clockwise direction among the plurality of first control points, and
wherein the first starting control point is selected based on a combination of at least two of types of the plurality of first control points, a length between the current control point and the previous control point adjacent thereto, a length between the current control point and the next control point adjacent thereto, and an angle of the normal direction relative to a reference line.

8. The OPC method of claim 2,
wherein the generating of the second curvilinear pattern layout includes:
selecting a new starting control point by grouping two or more control points around a control point having a relatively large EPE among the plurality of first control points.

9. The OPC method of claim 1, further comprising, before the generating of the retarget curve line:
dividing an edge of the polygonal pattern layout into a plurality of segments; and
generating a plurality of initial control points on the edge of the polygonal pattern layout,
wherein the generating of the retarget curve line comprises:
generating the retarget curve line which is inscribed in the polygonal pattern layout, and
wherein the retarget curve line includes a round portion at a position corresponding to a vertex of the polygonal pattern layout.

10. The OPC method of claim 9,
wherein the plurality of initial control points comprise a division point that is a division position for the plurality of segments, a vertex point that is a vertex of the polygonal pattern layout, and an additional point that is on the plurality of segments between adjacent vertices of the polygonal pattern layout, and
wherein the generating of the plurality of first control points comprises shifting the plurality of initial control points in the normal direction onto the retarget curve line.

11. An optical proximity correction (OPC) method comprising:
dividing an edge of a polygonal pattern layout of a target pattern into a plurality of segments;
generating a plurality of initial control points on the edge of the polygonal pattern layout;
generating a retarget curve line which is inscribed in the polygonal pattern layout, wherein the retarget curve line includes a round portion at a position corresponding to a vertex of the polygonal pattern layout;
generating a plurality of first control points by shifting the plurality of initial control points onto the retarget curve line;
generating a first curvilinear pattern layout based on the plurality of first control points;
extracting a contour of the target pattern through a simulation by inputting data of the first curvilinear pattern layout to an OPC model;
calculating an edge placement error (EPE), which is a difference between the contour and an edge of the target pattern;
determining whether to re-perform the extracting of the contour;
when it is determined to re-perform the extracting of the contour, shifting the plurality of first control points to a plurality of second control points, wherein a first starting control point among the plurality of first control points is shifted in a first direction that is different from a normal direction relative to the first curvilinear pattern layout at the first starting control point; and
when it is determined not to re-perform the extracting of the contour, determining the first curvilinear pattern layout as an OPCed layout,
wherein, after the shifting of the plurality of first control points to the plurality of second control points, the generating of the first curvilinear pattern layout is performed based on the plurality of second control points to generate a second curvilinear pattern layout.

12. The OPC method of claim 11,
wherein the first direction corresponds to a direction obtained by rotating the normal direction by a moving angle in a positive direction or a negative direction,
wherein with respect to the first starting control point, the positive direction is set to a rotation direction of the normal direction toward one of a long-edge line of the polygonal pattern layout and a short-edge line, directly connected to the long-edge line, of the polygonal pattern layout, and the negative direction is set to a rotation direction of the normal direction toward the other of the long-edge line and the short-edge line, and
wherein the second curvilinear pattern layout maintains top-bottom and left-right symmetry.

13. The OPC method of claim 11,
wherein the plurality of first control points are classified into various types according to a shape of the polygonal pattern layout,
wherein a previous control point, a current control point, and a next control point are defined in a clockwise direction among the plurality of first control points, and
wherein the first starting control point is selected based on one of types of the plurality of first control points, a length between the current control point and the previous control point adjacent thereto, a length between the current control point and the next control point adjacent thereto, and an angle of the normal direction relative to a reference line, or is selected based on a combination of at least two of the types of the plurality of first control points, the length between the current control point and the previous control point adjacent thereto, the length between the current control point and the next control point adjacent thereto, and the angle of the normal direction.

14. The OPC method of claim 11,
wherein the generating of the second curvilinear pattern layout includes:
selecting a new starting control point by grouping two or more control points around a control point having a relatively large EPE among the plurality of first control points.

15. The OPC method of claim 11,
wherein the plurality of initial control points comprise a division point that is a division position for the plurality of segments, a vertex point that is a vertex of the polygonal pattern layout, and an additional point that is on the plurality of segments between adjacent vertices of the polygonal pattern layout, and
wherein the generating of the plurality of first control points comprises shifting the plurality of initial control points along the retarget curve line.

16. A method of manufacturing a mask, the method comprising:
generating a retarget curve line corresponding to a polygonal pattern layout of a target pattern, wherein two adjacent edges of the polygonal pattern layout are perpendicular to each other;
generating a plurality of first control points on the retarget curve line;
generating a first curvilinear pattern layout based on the plurality of first control points;
extracting a contour of the target pattern through a simulation by inputting data of the first curvilinear pattern layout to an optical proximity correction (OPC) model;
calculating an edge placement error (EPE), which is a difference between the contour and an edge of the target pattern;
determining whether to re-perform the extracting of the contour;
when it is determined to re-perform the extracting of the contour, shifting the plurality of first control points to a plurality of second control points;
when it is determined not to re-perform the extracting of the contour, determining the first curvilinear pattern layout as an OPCed layout;
transferring data of the OPCed layout as mask tape-out (MTO) design data;
preparing mask data based on the MTO design data; and
performing exposure on a substrate based on the mask data to form a mask,
wherein, in the shifting of the plurality of first control points to the plurality of second control points, a first starting control point, which is at least some of the plurality of first control points, is shifted in a first direction that is different from a normal direction relative to the first curvilinear pattern layout at the first starting control point, and
wherein after the shifting of the plurality of first control points to the plurality of second control points, the generating of the first curvilinear pattern layout is performed based on the plurality of second control points to generate a second curvilinear pattern layout.

17. The method of claim 16,
wherein the first direction corresponds to a direction obtained by rotating the normal direction by a moving angle in a positive direction or a negative direction,
wherein with respect to the first starting control point, the positive direction is set to a rotation direction of the normal direction toward one of a long-edge line of the polygonal pattern layout and a short-edge line, directly connected to the long-edge line, of the polygonal pattern layout, and the negative direction is set to a rotation direction of the normal direction toward the other of the long-edge line and the short-edge line, and
wherein the second curvilinear pattern layout maintains top-bottom and left-right symmetry.

18. The method of claim 16,
wherein the plurality of first control points are classified into various types according to a shape of the polygonal pattern layout,
wherein a previous control point, a current control point, and a next control point are defined in a clockwise direction among the plurality of first control points, and
wherein the first starting control point is selected based on one of types of the plurality of first control points, a length between the current control point and the previous control point adjacent thereto, a length between the current control point and the next control point adjacent thereto, and an angle of the normal direction relative to a reference line, is selected based on a combination of at least two of the types of the plurality of the first control points, the length between the current control point and the previous control point adjacent thereto, the length between the current control point and the next control point adjacent thereto, and the angle of the normal direction, or is selected by grouping two or more control points around a control point having a relatively large EPE among the plurality of first control points.

19. The method of claim 16, further comprising:
before the generating of the retarget curve line:
dividing an edge of the polygonal pattern layout into a plurality of segments; and
generating a plurality of initial control points on the edge of the polygonal pattern layout,
wherein the generating of the retarget curve line comprises:
generating the retarget curve line which is inscribed in the polygonal pattern layout, and
wherein the retarget curve line includes a round potion at position corresponding to a vertex of the polygonal pattern layout.

20. The method of claim 19,
wherein the initial control points comprise a division point that is a division position for the segments, a vertex point that is a vertex of the polygonal pattern layout, and an additional point that is on the plurality of segments between adjacent vertices, and
wherin the generating of the control points comprises generating by shifting the initial control points in the normal direction onto the retarget curve line.
